(19) United States
(12) Patent Application Publication
(10) Pub. No.: US 2026/0130178 A1
(43) Pub. Date: May 7, 2026

(54) MEMORY DEVICE AND METHOD OF MANUFACTURING THE SAME

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 19/096,294

(22) Filed: Mar. 31, 2025

(30) Foreign Application Priority Data
Nov. 7, 2024 (KR) 10-2024-0157182

(51) Int. Cl. H01L 21/66; H10B 43/27

(52) U.S. Cl. CPC H10P 74/273; H10B 43/27

(57) ABSTRACT

A memory device, and a method of manufacturing the same, includes a stacked body in which conductive layers and interlayer insulating layers are alternately stacked in a stacking direction. The memory device also includes a chip guard enclosing a chip area of the stacked body, the chip guard penetrating through the stacked body in the stacking direction. The memory device further includes test electrodes electrically coupled to the chip guard. The test electrodes are spaced apart from each other, and at least a portion of the chip area is disposed between the test electrodes.

### CROSS-REFERENCE TO RELATED APPLICATION

The present application claims priority under 35 U.S.C. § 119(a) to Korean patent application number 10-2024-0157182 filed on Nov. 7, 2024, in the Korean Intellectual Property Office, the entire contents of which application is incorporated herein by reference.

### BACKGROUND

### 1. Technical Field

Various embodiments of the present disclosure relate to a memory device and a method of manufacturing the memory device, and more particularly, to a memory device including a memory block having a three-dimensional (3D) structure and a method of manufacturing the memory device.

### 2. Related Art

Through a semiconductor integration process, a plurality of chip areas may be formed on a semiconductor substrate. The plurality of chip areas may be distinguished from each other by using a scribe lane area as a boundary. The chip areas are separated from each other through a cutting process, and thus a plurality of semiconductor chips may be manufactured.

Each of the semiconductor chips may include a nonvolatile memory device in which stored data is retained even when supplied power is interrupted. The nonvolatile memory device may be classified as a two-dimensional (2D) structure or a three-dimensional (3D) structure according to the structure in which memory cells are arranged. The memory cells of a nonvolatile memory device having a 2D structure may be arranged in a single layer on a substrate, and the memory cells of a nonvolatile memory device having a 3D structure may be vertically stacked on a substrate. Because the degree of integration of the nonvolatile memory device having a 3D structure is higher than that of the nonvolatile memory device having a 2D structure, the number of electronic devices using the nonvolatile memory device having a 3D structure has recently increased.

### SUMMARY

In accordance with an embodiment of the present disclosure, a memory device may include: a stacked body in which conductive layers and interlayer insulating layers are alternately stacked in a stacking direction; a chip guard enclosing a chip area of the stacked body, the chip guard penetrating through the stacked body in the stacking direction; and test electrodes electrically coupled to the chip guard. The test electrodes are spaced apart from each other, and at least a portion of the chip area is disposed between the test electrodes.

In accordance with an embodiment of the present disclosure, a method of manufacturing a memory device may include: forming a stacked body in which sacrificial layers and interlayer insulating layers are alternately stacked; forming first and second sets of openings passing through the stacked body; forming cell plugs filling the first set of the openings; forming a vertical structure filling the second set of the openings; replacing the sacrificial layers with conductive layers; forming a chip guard, wherein the chip guard includes the vertical structure; forming test electrodes that are electrically connected to the chip guard and to a test circuit, wherein the test circuit is configured to determine, using an electrical signal input to the chip guard through the test electrodes, whether a defect has occurred in the stacked body.

### BRIEF DESCRIPTION OF THE DRAWINGS

FIG. 1 shows a view illustrating the structure of a memory device according to an embodiment of the present disclosure.

FIGS. 2A and 2B show views for describing a memory device including a chip guard according to the present disclosure.

FIGS. 3A, 3B, and 3C show views illustrating the arrangement of test electrodes and the planar shape of a chip guard according to various embodiments of the present disclosure.

FIGS. 4A and 4B show views for describing a memory device including a chip guard and a detection circuit according to the present disclosure.

FIGS. 5A and 5B show views for describing a memory device including a chip guard and a memory cell array according to the present disclosure.

FIGS. 6A, 6B, 6C, 6D, and 6E show views for describing a method of manufacturing a memory device including a chip guard according to the present disclosure.

FIG. 7 is a diagram illustrating a memory card system to which a memory device according to the present disclosure is applied.

FIG. 8 is a diagram illustrating a solid-state drive (SSD) system to which a memory device according to the present disclosure is applied.

### DETAILED DESCRIPTION

Specific structural or functional descriptions in embodiments of the present disclosure introduced in this specification or application are provided as examples to describe embodiments according to the concept of the present disclosure. Embodiments according to the concept of the present disclosure may be practiced in various forms and should not be construed as being limited to embodiments described in the specification or application.

Hereinafter, various embodiments of the present disclosure are described in detail with reference to the accompanying drawings in which embodiments of the present disclosure are shown so that those skilled in the art to which the present disclosure pertains can practice the technical spirit of the present disclosure.

Some embodiments of the present disclosure are directed to a memory device and a method of manufacturing the memory device, which may enhance the ability to identify whether defects have occurred in an area adjacent to a chip guard.

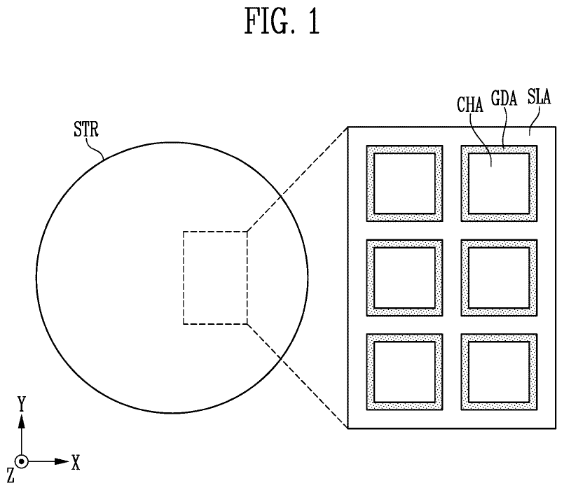

FIG. 1 shows a view illustrating the structure of a memory device according to an embodiment of the present disclosure.

The memory device may include a structure STR. For example, the structure STR may include a substrate (e.g., a silicon wafer, a SiGe wafer, or an SOI wafer) and material patterns formed on the substrate.

Referring to FIG. 1, the structure STR may include chip areas CHA, guard areas GDA, and a scribe lane area. For example, the structure STR may include chip areas CHA, guard areas GDA enclosing the chip areas CHA, respectively, and a scribe lane area SLA enclosing the guard areas GDA.

The chip areas CHA may be areas in which semiconductor chips are formed. The chip areas CHA may be arranged along an X direction and a Y direction. Semiconductor chips may be formed, respectively, through a semiconductor integration process performed on the chip areas CHA. For example, when each of the semiconductor chips formed in the chip areas CHA includes a memory cell array, respective semiconductor chips may be memory devices. The semiconductor chips respectively formed in the plurality of chip areas CHA in one structure STR may be substantially identical. After the semiconductor integration process is completed on the substrate, the structure STR is separated into respective chip areas CHA, and thus the chip areas CHA may be separated in the form of semiconductor chips.

The guard areas GDA may be adjacent to the chip areas CHA, respectively. The guard areas GDA may enclose the chip areas CHA, respectively. For example, a guard area GDA may be formed within a distance from the boundary surface of a corresponding chip area CHA. When the plane of each chip area CHA has a rectangular shape, the plane of the corresponding guard area GDA may have the shape of a rectangle with a hollow center to enclose the periphery of the chip area CHA. The side surface of the chip area CHA and the inner surface of the corresponding guard area GDA may contact each other.

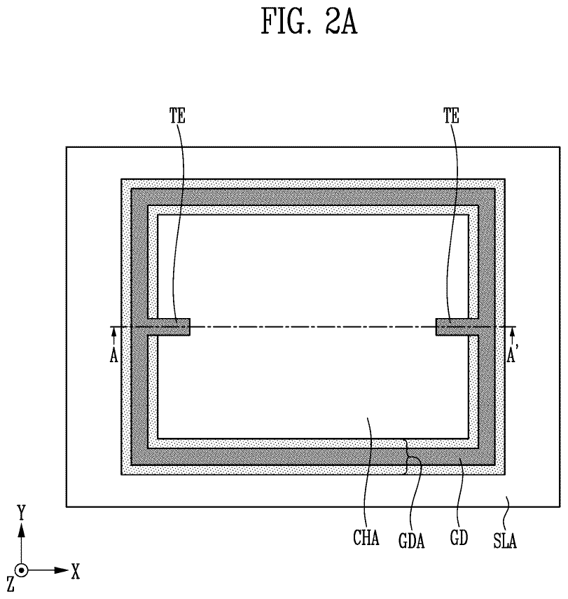

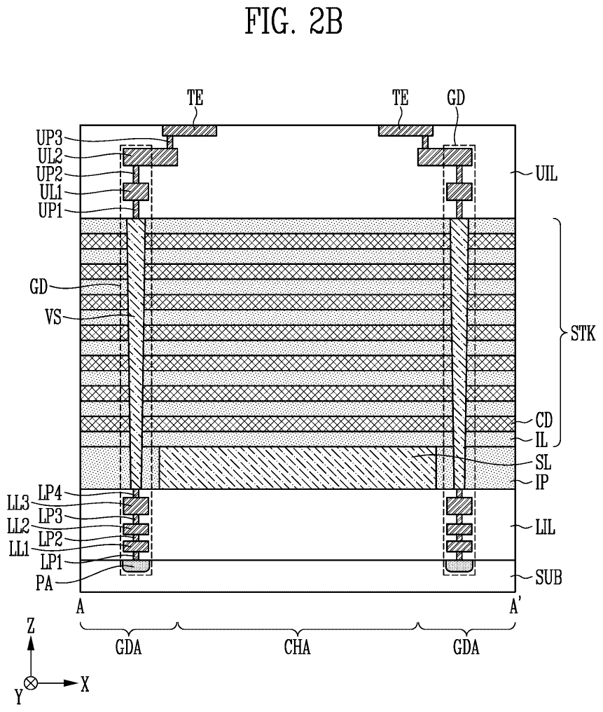

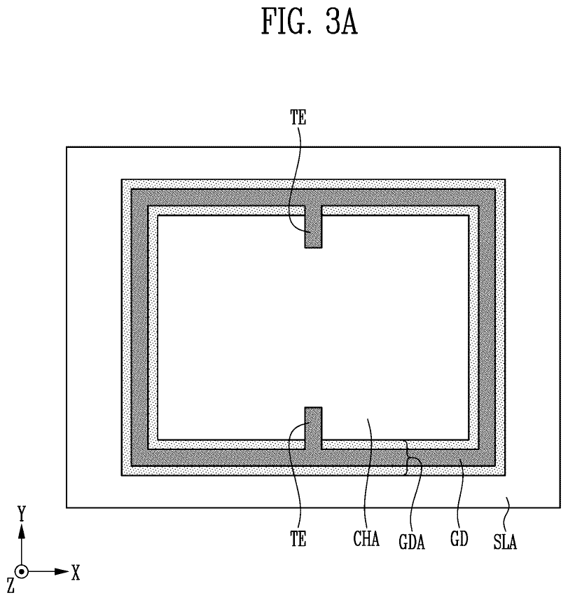

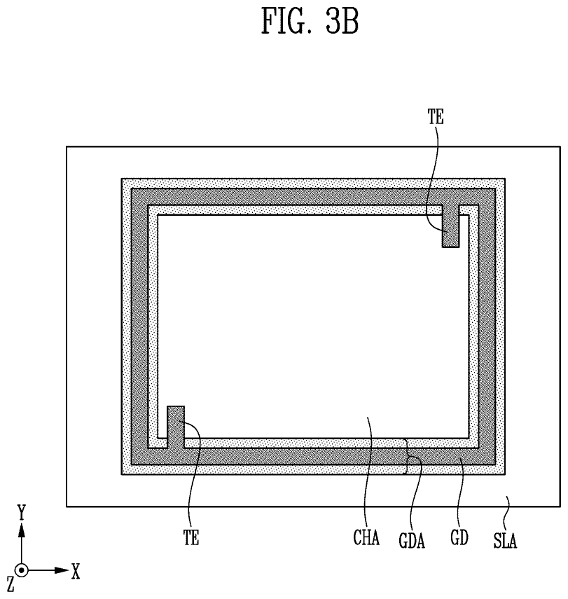

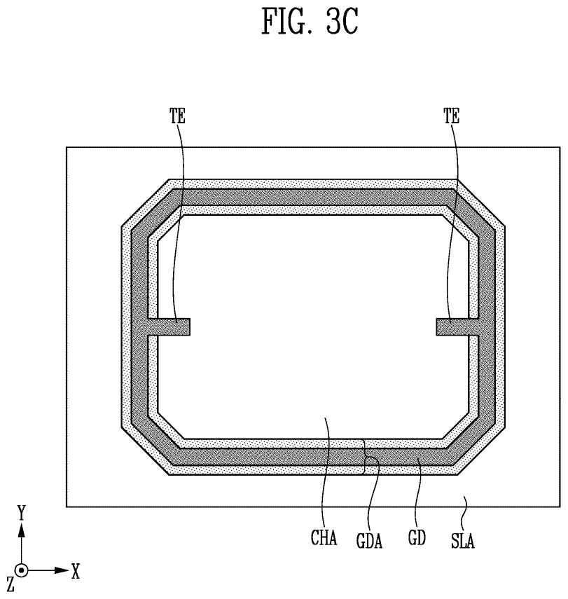

In the guard areas GDA, chip guards may be formed. The chip guards may prevent moisture or oxygen from permeating into the respective chip areas CHA from the outside of the chip areas CHA. Furthermore, the chip guards may reduce interference between dies at a packaging step performed after the chip areas CHA are separated as respective semiconductor chips. The shapes of the chip guards formed in the guard areas GDA is described in detail later with reference to FIGS. 2A and 3A to 3C.

The scribe lane area SLA may be outside the chip areas CHA and the guard areas GDA. For example, the scribe lane area SLA may be disposed between the chip areas CHA. Furthermore, the scribe lane area SLA may enclose the guard areas GDA. After the semiconductor integration process is completed, the scribe lane area SLA may be cut during a dicing process of separating the semiconductor chips. The structure STR is cut along the scribe lane area SLA, whereby the chip areas CHA may be individually separated. Each separated semiconductor chip may include a chip area CHA and a corresponding guard area GDA enclosing the chip area CHA. As a process of cutting the structure STR, methods such as a sawing process using a blade, a laser process using a laser, or a stealth dicing process may be employed. In an embodiment, an electrical test pattern, a process monitoring pattern, and an alignment key may be arranged in the scribe lane area SLA.

Although six chip areas CHA are illustrated in FIG. 1 for convenience of description, the scope of the present disclosure is not limited by this structure. For example, the structure STR may include various numbers of (e.g., seven or more) chip areas CHA. In addition, in the present disclosure, although the chip areas CHA, the guard areas GDA, and the scribe lane area SLA are separately described, this is provided for convenience of description, and the chip areas CHA, the guard areas GDA, and the scribe lane area SLA may be successively connected to each other without being physically separated. For example, respective boundary surfaces of the chip areas CHA, the guard areas GDA, and the scribe lane area SLA might not be clearly observed. Furthermore, in the structure STR, the locations of the chip areas CHA, the guard areas GDA, and the scribe lane area may be arbitrarily determined. In the present disclosure, the chip areas CHA, the guard areas GDA, and the scribe lane area SLA may refer to a limited space within a range in a horizontal direction in the structure STR rather than referring to an area in the substrate.

FIGS. 2A and 2B show views for describing a memory device including a chip guard according to the present disclosure. FIG. 2A shows a plan view for describing the layout of a memory device. FIG. 2B shows a sectional view taken along line A-A′ of FIG. 2A.

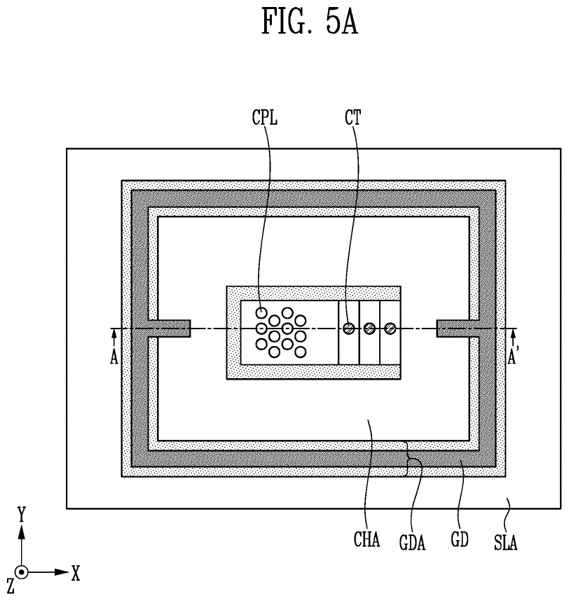

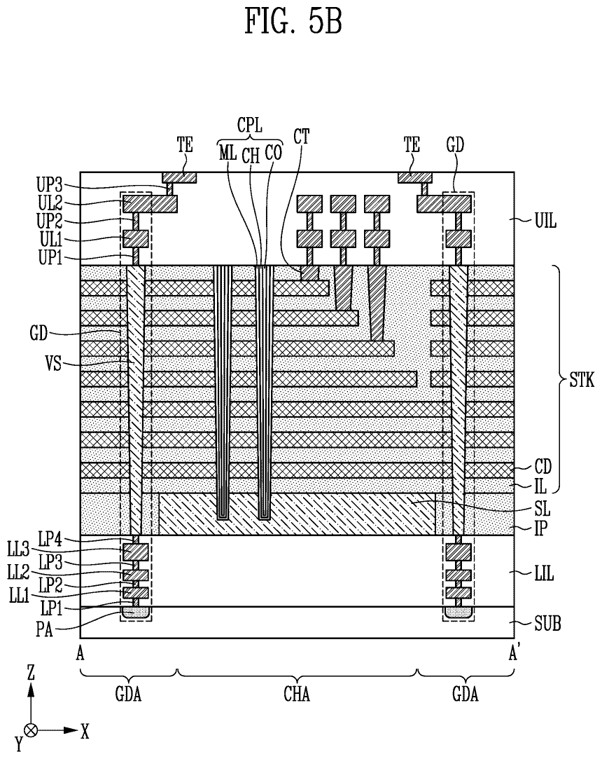

Referring to FIG. 2A, the chip area CHA may be enclosed by a scribe lane area SLA and a guard area GDA. Although not illustrated in the drawings, the chip area CHA may include a central region including the center of the chip area CHA. A memory cell array may be arranged in the central region of the chip area CHA. The memory cell array is described in detail later with reference to FIGS. 5A and 5B.

In the guard area GDA, a chip guard GD may be formed. The chip guard GD may enclose the chip area CHA. The chip guard GD may extend along the boundary of the chip area CHA. For example, the chip area CHA may represent a rectangular plane, and the chip guard GD may have a shape extending along four side surfaces of the chip area CHA. The chip guard GD may directly contact the interface of the chip area CHA or may be spaced apart from the surface of the chip area CHA. The scribe lane area SLA may be outside the chip guard GD. The planar shape of each of the chip area CHA and the chip guard GD, illustrated in FIG. 2A, is only an example, and does not limit the scope of the present disclosure. An example of the planar shape of each of the chip area CHA and the chip guard GD is described later with reference to FIG. 3C.

The test electrodes TE may be coupled to the chip guard GD. The test electrodes TE may be spaced apart from each other, and at least a portion of the chip area CHA may be disposed between the test electrodes TE. The test electrodes TE may be formed to be spaced apart from each other, and a central region including the center of the chip area CHA may be disposed between the test electrodes TE. For example, the test electrodes TE may be arranged symmetrically with respect to the central region of the chip area CHA. For example, one of the test electrodes TE may be formed to contact an area of the chip guard GD in the positive X direction from the chip area CHA, and the other test electrode TE may be formed to contact an area of the chip guard GD in the negative X direction from the chip area CHA. In addition, various arrangements of the test electrodes TE are described in detail later with reference to FIGS. 3A and 3B.

The test electrodes TE may extend from the chip guard GD into the chip area CHA. The test electrodes TE may extend from the guard area GDA into the chip area CHA. Portions of respective test electrodes TE may be in the chip area CHA, and other portions of the test electrodes TE may be in the guard area GDA.

Referring to FIG. 2B, the memory device may include a stacked body STK. The stacked body STK may include conductive layers CD and interlayer insulating layers IL that are alternately stacked. The conductive layers CD and the interlayer insulating layers IL may be alternately stacked in a Z direction. The conductive layers CD may be used as select lines or word lines of the memory device. Each of the conductive layers CD may contain at least one of tungsten (W), cobalt (Co), nickel (Ni), molybdenum (Mo), silicon (Si), or polysilicon (Poly-Si). The interlayer insulating layers IL may insulate the conductive layers CD from each other. For example, each of the interlayer insulating layers IL may include an oxide layer (e.g., a silicon oxide layer).

The stacked body STK may extend from the chip area CHA into the guard area GDA. For example, the chip area CHA may include a portion of the stacked body STK. Also, the guard area GDA may include another portion of the stacked body STK. Although not illustrated in the drawings, the stacked body STK may further extend from the chip area CHA and the guard area GDA into the scribe lane area SLA.

A substrate SUB may be arranged below the stacked body STK. The substrate SUB may extend from the chip area CHA to the guard area GDA. The substrate SUB may extend in an X direction and a Y direction. For example, the substrate SUB may be a silicon wafer, a SiGe wafer, or a SOI wafer.

The substrate SUB may include an active area PA. The active area PA may be an area into which impurities are injected into the substrate SUB. The impurities may include group 13 or group 15 elements of the periodic table. For example, the impurities may be boron (B), indium (In), from group 13, or phosphorus (P), from group 15.

A lower insulating layer LIL may be between the stacked body STK and the substrate SUB. The lower insulating layer LIL may be on the substrate SUB. The lower insulating layer LIL may be formed as a single-layer structure or a multi-layer structure. The lower insulating layer LIL may contain an insulating material (e.g., an oxide).

A semiconductor layer SL and insulating patterns IP may be arranged between the stacked body STK and the lower insulating layer LIL. The insulating patterns IP may penetrate the semiconductor layer SL. The semiconductor layer SL and the insulating patterns IP may be at the same level. The semiconductor layer SL may be in at least a portion of the chip area CHA. The insulating patterns IP may be in the guard area GDA. Although not illustrated in the drawings, insulating patterns IP may also be formed in the chip area CHA. The semiconductor layer SL may contain undoped silicon or doped silicon. The insulating patterns IP may contain an oxide material.

An upper insulating layer UIL may be arranged on the stacked body STK. The upper insulating layer UIL may be formed as a single-layer structure or a multi-layer structure. The upper insulating layer UIL may contain an insulating material (e.g., an oxide).

The chip guard GD may be in the guard area GDA. The chip guard GD may extend in the Z direction. The chip guard GD may penetrate the stacked body STK. The chip guard GD may extend in the Z direction within the stacked body STK. The chip guard GD may have a shape extending in the Z direction to prevent moisture or oxygen from permeating into the chip area CHA from the outside of the chip area CHA.

The chip guard GD may extend in a horizontal direction. For example, a portion of the chip guard GD, located in the X direction of the chip area CHA, may extend in a Y direction. Further, a portion of the chip guard GD, located in the Y direction of the chip area CHA, may extend in the X direction. The chip guard GD may extend along the direction in which the side surface of the chip area CHA extends.

The chip guard GD may include a vertical structure VS penetrating the stacked body STK. The vertical structure VS may penetrate through the stacked body STK. The vertical structure VS may extend in the Z direction within the stacked body STK. The vertical structure VS may extend into the insulating patterns IP. For example, the vertical structure VS may penetrate the insulating patterns IP. The vertical structure VS may be formed of a multi-layer structure. For example, the vertical structure VS may include a conductive pillar containing a conductive material, and an insulating spacer enclosing the conductive pillar.

In an embodiment, the vertical structure VS may include a plurality of pillar structures. For example, the vertical structure VS may include a plurality of pillar structures arranged in an X direction or a Y direction. The pillar structures may be arranged to enclose the periphery of the chip area CHA. The pillar structures may be arranged in parallel along the boundary of the chip area CHA. Each of the pillar structures may extend in the Z direction.

In an embodiment, the vertical structure VS may have a shape extending in a horizontal direction. For example, the vertical structure VS may extend along the X direction or the Y direction. The vertical structure VS may have the shape of a slit or a plate extending along the interface of the chip area CHA. In addition, the vertical structure VS included in the chip guard GD may be formed in various shapes penetrating the stacked body STK.

The chip guard GD may include at least one upper line and at least one upper plug which are located on the stacked body STK. For example, the chip guard GD may include a first upper plug UP1, a first upper line UL1, a second upper plug UP2, and a second upper line UL2 which are located on the stacked body STK. The first upper plug UP1, the first upper line UL1, the second upper plug UP2, and the second upper line UL2 may be enclosed by the upper insulating layer UIL. The first upper plug UP1 may contact the upper surface of the vertical structure VS. Each of the first upper plug UP1, the first upper line UL1, the second upper plug UP2, and the second upper line UL2 may contain a conductive material.

Also, the chip guard GD may include at least one lower line and at least one lower plug which are located under the stacked body STK. For example, the chip guard GD may include a first lower plug LP1, a first lower line LL1, a second lower plug LP2, a second lower line LL2, a third lower plug LP3, a third lower line LL3, and a fourth lower plug LP4 which are located under the stacked body STK. The first lower plug LP1, the first lower line LL1, the second lower plug LP2, the second lower line LL2, the third lower plug LP3, the third lower line LL3, and the fourth lower plug LP4 may be enclosed by the lower insulating layer LIL. The fourth lower plug LP4 may contact the lower surface of the vertical structure VS. Each of the first lower plug LP1, the first lower line LL1, the second lower plug LP2, the second lower line LL2, the third lower plug LP3, the third lower line LL3, and the fourth lower plug LP4 may include a conductive material.

The chip guard GD may include an active area PA in the substrate SUB. The first lower plug LP1 may be directly connected to the active area PA.

The chip guard GD may have a shape extending from the substrate SUB into the upper insulating layer UIL via the stacked body STK. In an embodiment, the chip guard GD may decrease the permeation of moisture and/or oxygen from outside the chip guard GD into the chip area CHA.

The number, arrangement, and connection relationships of the upper lines, the upper plugs, the lower lines, and the lower plugs illustrated in FIG. 2B may vary in different embodiments. In an example, the chip guard GD may include lower lines having a smaller or larger number of layers than those illustrated in FIG. 2B. In an example, the first to fourth lower plugs LP1 to LP4 may be aligned in the Z direction, as illustrated in FIG. 2B, or might not overlap each other in the Z direction, unlike illustration in FIG. 2B. In an example, when a cross-section taken along line A-A′ of FIG. 2A is compared to other cross-sections, the number of layers, arrangement locations, and connection relationships of the upper lines, the upper plugs, the lower lines, and the lower plugs may be different from each other.

The test electrodes TE may be electrically connected to the chip guard GD. Each of the test electrodes TE may be connected to the chip guard GD through the third upper plug UP3. The test electrodes TE may have a shape extending in the X direction. The test electrodes TE may be located at a level higher than that of the chip guard GD. The test electrodes TE might not overlap the chip guard GD in the Z direction. Each of third upper plugs UP3 may connect the test electrode TE to the corresponding second upper line UL2.

Unlike illustration in FIG. 2B, the test electrodes TE may be formed at the same level as a portion of the chip guard GD. For example, the test electrodes TE may be formed to directly contact the second upper lines UL2, respectively. Alternatively, the test electrodes TE may above the chip guard GD in the Z direction. The test electrodes TE may be formed to overlap the chip guard GD in the Z direction. As long as the test electrodes TE are connected to the chip guard GD, the positional relationship between the test electrodes TE and the chip guard GD does not limit the scope of the present disclosure.

The test electrodes TE may extend from the chip guard GD into the chip area CHA. Portions of respective test electrodes TE may be in the guard area GDA, and other portions of the test electrodes may be in the chip area CHA. However, unlike FIG. 2B, the test electrodes TE may be in the guard area GDA without extending into the chip area CHA.

During a process of manufacturing or testing semiconductor chips according to the present disclosure, whether defects have occurred in the stacked body STK may be identified using the test electrodes TE. In an embodiment, a memory device according to the present disclosure may further include a test circuit connected to the test electrodes TE. The test circuit may input an electrical signal to the chip guard GD through the test electrodes TE. Also, the test circuit may measure the resistance of the chip guard GD through the test electrodes TE. For example, the test circuit may obtain resistance gradient information through the test electrodes TE. The test circuit may identify whether defects have occurred in the stacked body STK using the resistance gradient information. For example, when a defect such as a crack occurs in a portion of the stacked body STK or in a portion of the chip guard GD penetrating the stacked body STK, or when a not-open defect in which a structure such as the chip guard GD cannot completely penetrate the stacked body STK occurs therein, the tendency of the resistance gradient information may differ from that of the case where no defect occurs in the stacked body STK. Therefore, when the resistance gradient information falls out of a designated range, the test circuit may detect the occurrence of defects in the stacked body STK.

In some embodiments, a separate test device may be connected to test a memory device according to the present disclosure. The test device may be electrically connected to the test electrodes TE. The test device may use the test electrodes TE as resistance measurement nodes. The test device may measure the resistance of the chip guard GD through the test electrodes TE. For example, the test device may obtain resistance gradient information through the test electrodes TE. The test device may identify whether defects have occurred in the stacked body STK using the resistance gradient information. Therefore, when the resistance gradient information falls outside a designated range, the test device may detect the occurrence of defects in the stacked body STK.

The test electrodes TE may be spaced apart from each other, and the chip area CHA may be disposed between the test electrodes TE. For example, the test electrodes TE may be arranged on the left and right sides of the chip area CHA, respectively. The test electrodes TE may be spaced as far apart as possible from each other so that the resistance of the chip guard GD located over a wider range can be measured. Additional embodiments related to the arrangement of the test electrodes TE are described later with reference to FIGS. 3A and 3B.

FIGS. 3A to 3C show views illustrating the arrangement of test electrodes and the planar shape of a chip guard according to various embodiments of the present disclosure.

Referring to FIGS. 3A and 3B, test electrodes TE may be spaced apart from each other, and at least a portion of a chip area CHA may be between the test electrodes TE. For example, the test electrodes TE may be arranged symmetrically with respect to a central region of the chip area CHA. The central region of the chip area CHA may refer to an arbitrary region including the central point of the chip area CHA in the chip area CHA.

Referring to FIG. 3A, one test electrode TE may be located in an area of a chip guard GD in the Y direction from the chip area CHA, and the other test electrode TE may be located in an area of the chip guard GD in the negative Y direction from the chip area CHA. The test electrodes TE may have a shape extending in the Y direction.

Referring to FIG. 3B, one test electrode TE may be arranged close to a first vertex of the chip guard GD, and the other test electrode TE may be arranged close to a second vertex of the chip guard GD, which is located in the opposite direction from the first vertex. The first vertex may be a vertex located in the X direction and the Y direction among four vertices of the chip guard GD, and the second vertex may be a vertex located in the negative X direction and the negative Y direction among the four vertices of the chip guard GD. Further, the fact that the first vertex and the second vertex are opposite each other may mean that the vertices are located in opposite directions with respect to the central region of the chip area CHA. Although, in FIG. 3B, the test electrodes TE are illustrated as being arranged close to the vertices of the chip guard GD, the test electrodes TE may also be arranged to contact the vertices, respectively. Further, although each of the test electrodes TE is illustrated as having a shape extending in the Y direction in FIG. 3B, the test electrodes TE may extend in various directions such as by extending toward the central region of the chip area CHA.

The arrangement of the test electrodes TE illustrated in FIGS. 2A, 3A, and 3B may correspond to some examples. In addition, the test electrodes TE may be arranged in different directions with respect to at least a portion of the chip area CHA. In the present disclosure, different directions may include directions opposite each other or directions crossing each other.

In FIGS. 2A, 3A, and 3B, although illustrations are made on the assumption that the plane of the chip area CHA has a rectangular shape, the planar shape of the chip area CHA is not limited to rectangles. For example, as shown in FIG. 3C, the plane of the chip area CHA may have an octagonal shape. When the chip area CHA has an octagonal plane, the chip guard GD extends along the side surface of the chip area CHA, and thus the chip guard GD may have an octagonal plane having a hollow center. Even if the plane of each of the chip area CHA and the chip guard GD changes from the rectangular shape to the octagonal shape, the test electrodes TE may be arranged in different directions with respect to at least a portion of the chip area CHA. For example, as shown in FIG. 3C, the test electrodes TE may be formed to contact two opposite corners, respectively, among eight corners of the chip guard GD.

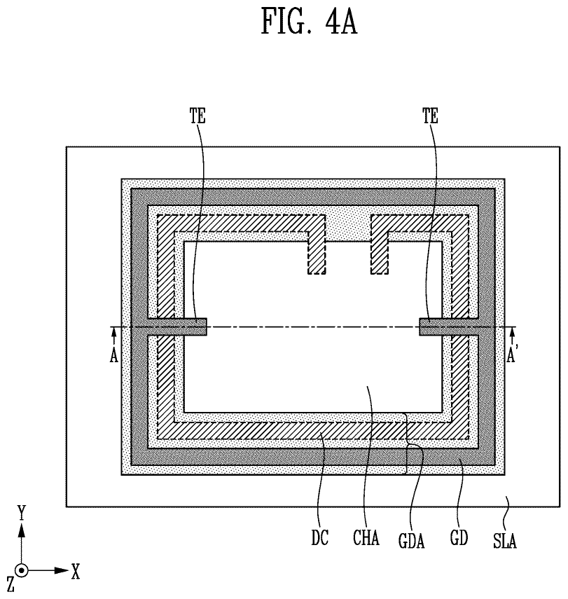

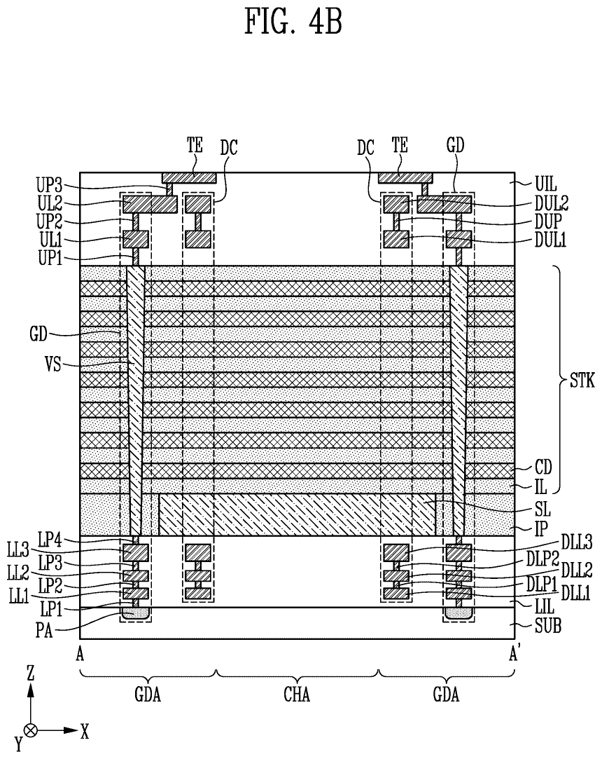

FIGS. 4A and 4B show views for describing a memory device including a chip guard and a detection circuit according to the present disclosure. FIG. 4A shows a plan view for describing the layout of a memory device. FIG. 4B shows a sectional view taken along line A-A′ of FIG. 4A. Among components illustrated in FIGS. 4A and 4B, description of components described in relation to FIGS. 2A and 2B and FIGS. 3A to 3C are omitted, or are made in brief.

Referring to FIG. 4A, a chip guard GD and a detection circuit DC may be formed in a guard area GDA. The detection circuit DC may be disposed between a chip area CHA and the chip guard GD. At least a portion of the detection circuit DC may enclose the chip area CHA. At least a portion of the detection circuit DC may extend along the side surface of the chip area CHA. The detection circuit DC may extend into the chip area CHA. A portion of the detection circuit DC may be in the guard area GDA, and another portion of the detection circuit DC may be in the chip area CHA.

Referring to FIG. 4B, the detection circuit DC may include at least one upper detection line and at least one upper detection plug which are located over a stacked body STK. For example, the detection circuit DC may include a first upper detection line DUL1, an upper detection plug DUP, and a second upper detection line DUL2, which are located over the stacked body STK. The first upper detection line DUL1, the upper detection plug DUP, and the second upper detection line DUL2 may be enclosed by an upper insulating layer UIL. The first upper detection line DUL1 may be located at the same level as a first upper line UL1. The upper detection plug DUP may be located at the same level as a second upper plug UP2. The second upper detection line DUL2 may be located at the same level as a second upper line UL2. Each of the first upper detection line DUL1, the upper detection plug DUP, and the second upper detection line DUL2 may contain a conductive material.

Also, the detection circuit DC may include at least one lower detection line and at least one lower detection plug which are located under the stacked body STK. For example, the detection circuit DC may include a first lower detection line DLL1, a first lower detection plug DLP1, a second lower detection line DLL2, a second lower detection plug DLP2, and a third lower detection line DLL3 which are located under the stacked body STK. The first lower detection line DLL1, the first lower detection plug DLP1, the second lower detection line DLL2, the second lower detection plug DLP2, and the third lower detection line DLL3 may be enclosed by a lower insulating layer LIL. The first lower detection line DLL1 may be located at the same level as a first lower line LL1. The first lower detection plug DLP1 may be located at the same level as a second lower plug LP2. The second lower detection line DLL2 may be located at the same level as a second lower line LL2. The second lower detection plug DLP2 may be located at the same level as a third lower plug LP3. The third lower detection line DLL3 may be located at the same level as a third lower line LL3. Each of the first lower detection line DLL1, the first lower detection plug DLP1, the second lower detection line DLL2, the second lower detection plug DLP2, and the third lower detection line DLL3 may contain a conductive material.

However, the number, arrangement, and connection relationships of the upper detection lines, the upper detection plugs, the lower detection lines, and the lower detection plugs, illustrated in FIG. 4B, indicate one embodiment, and do not limit the scope of the present disclosure. In an example, the detection circuit DC may include lower detection lines having a smaller or larger number of layers than those illustrated in FIG. 4B. In an example, the first and second lower detection plugs DLP1 and DLP2 may be aligned along the Z direction, as illustrated in FIG. 4B or might not overlap each other along the Z direction, unlike illustration in FIG. 4B. In an example, when a cross-section taken along line A-A′ of FIG. 4A is compared to other cross-sections, the numbers of layers, arrangement locations, and connection relationships of the upper detection lines, the upper detection plugs, the lower detection lines, and the lower detection plugs may be different from each other.

The detection circuit DC may be used to detect whether defects have occurred in the chip guard GD. The detection circuit DC may be formed adjacent to the chip guard GD. When a defect, such as a crack, occurs in the chip guard GD, it may be identified by the detection circuit DC.

The detection circuit DC might not penetrate the stacked body STK. The detection circuit DC may be located on or under the stacked body STK without extending into the stacked body STK. For example, first upper detection lines DUL1, upper detection plugs DUP, and second upper detection lines DUL2 (hereinafter referred to as an “upper detection circuit”) may be electrically connected to each other to enclose the periphery of the chip area CHA. Further, first lower detection lines DLL1, first lower detection plugs DLP1, second lower detection lines DLL2, second lower detection plugs DLP2, and third lower detection lines DLL3 (hereinafter referred to as a “lower detection circuit”) may be electrically connected to each other to enclose the periphery of the chip area CHA. However, the upper detection circuit and the lower detection circuit may be electrically insulated from each other.

When the detection circuit DC does not penetrate the stacked body STK, it is difficult to identify whether defects have occurred in the chip guard GD at a level corresponding to the stacked body STK. Therefore, when defects occur in a portion of the chip guard GD at the level corresponding to the stacked body STK, the defects might not be detected by the detection circuit DC. However, according to the present disclosure, in addition to the detection circuit DC, test electrodes TE connected to the chip guard GD are further formed. As a result, even if a defect, such as a crack, or a not-open defect occurs at the level corresponding to the stacked body STK, it may be possible to detect the defect, such as the crack, or the not-open defect.

FIGS. 5A and 5B show views for describing a memory device including a chip guard and a memory cell array according to the present disclosure. FIG. 5A shows a plan view for describing the layout of a memory device. FIG. 5B shows a sectional view taken along line A-A′ of FIG. 5A. Among components illustrated in FIGS. 5A and 5B, description of components described in relation to FIGS. 2A and 2B and FIGS. 3A to 3C are omitted, or are made in brief.

Referring to FIG. 5A, a memory cell array may be formed in a chip area CHA. For example, the memory cell array may be formed in a central region of the chip area CHA including the center of the chip area CHA. The memory cell array may include cell plugs CPL and contacts CT. Test electrodes TE may be located in different directions with respect to the memory cell array. For example, the test electrodes TE may be arranged in opposite directions (e.g., on left and right sides) with respect to at least one cell plug CPL.

Referring to FIG. 5B, the cell plugs CPL may penetrate through the stacked body STK in the chip area CHA. Each of the cell plugs CPL may include a memory layer ML, a channel layer CH, and a core pillar CO. In an embodiment, the memory layer ML may have a cylindrical shape. The plane, or X-Y cross section, of the memory layer ML may have a circular shape. The memory layer ML may enclose the periphery of the channel layer CH. Although not illustrated in the drawings, the memory layer ML may include a blocking layer, a charge trap layer, and a tunneling layer. In an embodiment, the plane of the memory layer ML may have an elliptical shape or a clover shape. However, for convenience of description, it is assumed that the planar shape of the cell plugs CPL is circular.

The blocking layer and the tunneling layer which are included in the memory layer ML may be formed of an oxide layer (e.g., a silicon oxide layer) or an oxynitride layer (e.g., a silicon oxynitride layer), or a combination thereof. The charge trap layer included in the memory layer ML may include a nitride layer or a variable resistance material.

The channel layer CH may be formed along the inner wall of the memory layer ML. The core pillar CO may fill the channel layer CH. The core pillar CO may have the shape of a cylinder enclosed by the channel layer CH. The channel layer CH may be formed of an undoped silicon layer or a doped silicon layer. The core pillar CO may be formed of an insulating layer (e.g., oxide layer) or a conductive layer.

The cell plugs CPL may extend into a semiconductor layer SL. The cell plugs CPL may contact the semiconductor layer SL. For example, the channel layer CH may directly contact the semiconductor layer SL.

The contacts CT may be connected to the conductive layers CD, respectively, in the chip area CHA. The conductive layers CD may have a step structure, and the contacts CT may contact end portions, respectively, included in the step structure. The contacts CT may contain a conductive material. In an embodiment, unlike illustration illustrated in FIG. 5B, the conductive layers CD might not include a step structure. In a stacked body STK that is not formed with a step structure, openings for exposing the respective conductive layers CD may be formed, and contacts CT may be formed in the openings, respectively.

A vertical structure VS of the chip guard GD may have a width corresponding to the cell plugs CPL. For example, the opening filled with the vertical structure VS and openings filled with the cell plugs CPL may be formed through a single etching process. That is, openings passing through the stacked body STK may be formed through an etching process of etching a portion of the stacked body STK, the vertical structure VS may be formed in some of the openings, and the cell plugs CPL may be formed in other openings. Therefore, the width of the vertical structure VS in the X direction may be equal to the width of the cell plugs CPL in the X direction.

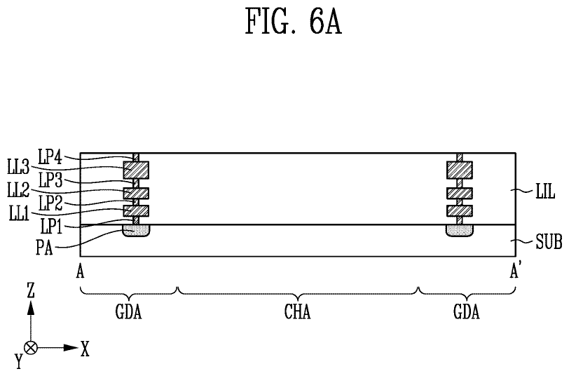

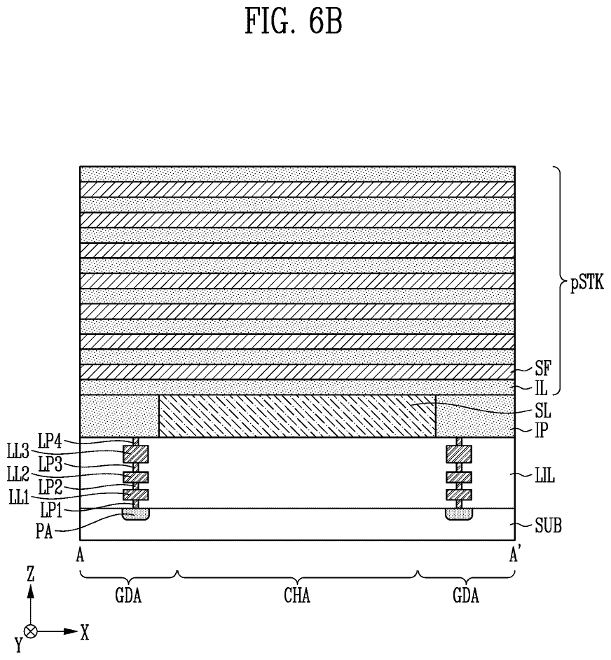

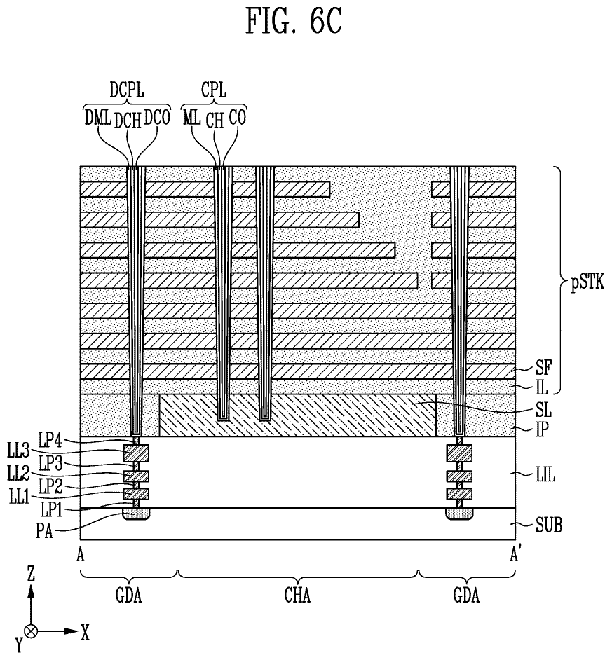

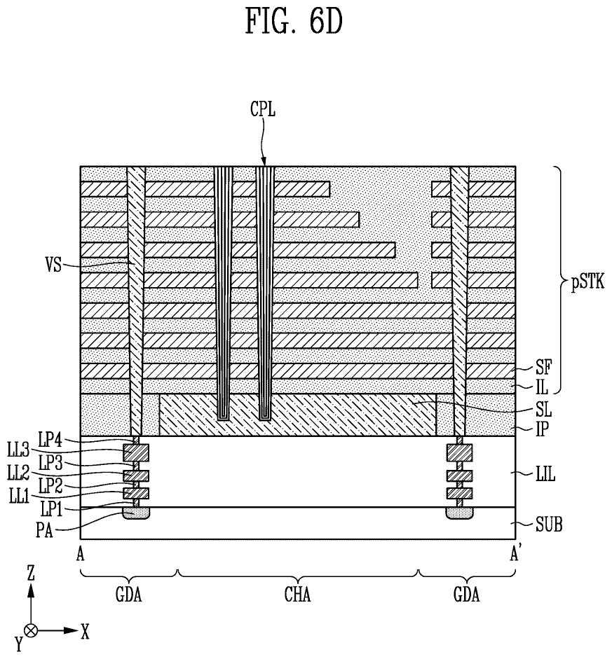

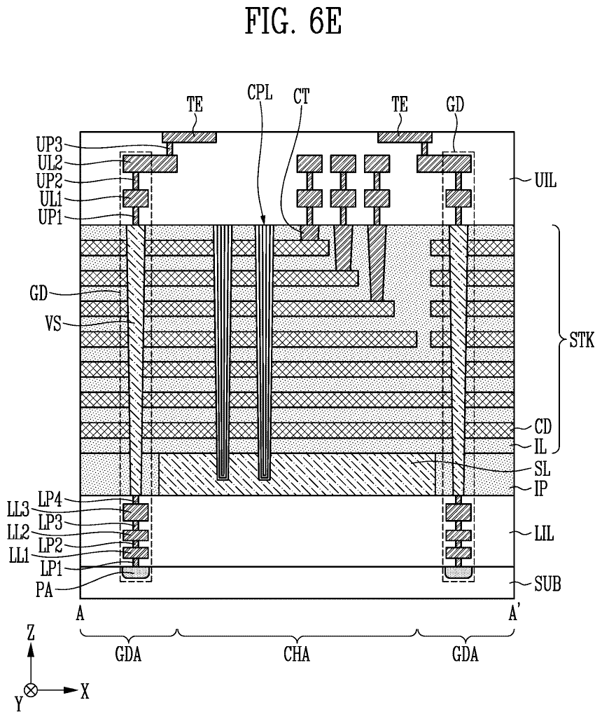

FIGS. 6A to 6E show views for describing a method of manufacturing a memory device including a chip guard according to the present disclosure. FIGS. 6A to 6E correspond to sectional views of line A-A′ of FIG. 5A.

Referring to FIG. 6A, an active area PA may be formed in a substrate SUB. The active area PA may be formed in a guard area GDA. The active area PA may be formed to include sub-areas that are extending into each other or are separated from each other. The active area PA may be formed by injecting impurities (e.g., group 13 or group 15 elements of the periodic table) into the substrate SUB.

Subsequently, first lower plugs LP1, first lower lines LL1, second lower plugs LP2, second lower lines LL2, third lower plugs LP3, third lower lines LL3, and fourth lower plugs LP4 may be formed on the substrate SUB. The first lower plugs LP1, the first lower lines LL1, the second lower plugs LP2, the second lower lines LL2, the third lower plugs LP3, the third lower lines LL3, and the fourth lower plugs LP4 may be formed in the guard area GDA. The first lower plugs LP1, the first lower lines LL1, the second lower plugs LP2, the second lower lines LL2, the third lower plugs LP3, the third lower lines LL3, and the fourth lower plugs LP4 may be enclosed by a lower insulating layer LIL. Although not illustrated in the drawings, lower lines and lower plugs which are electrically connected to the memory cell array may be additionally formed, even in the chip area CHA.

For example, after a first insulating layer having a thickness is formed, a partial region of the first insulating layer may be etched, and the first lower plugs LP1 may be formed in the etched region. After a second insulating layer that covers the first lower plugs LP1 is formed, a partial region of the second insulating layer may be etched, and the first lower lines LL1 may be formed in the etched region. In this way, the lower lines and the lower plugs may be sequentially formed in the Z direction.

Referring to FIG. 6B, a semiconductor layer SL and insulating patterns IP may be formed on the lower insulating layer LIL. For example, the semiconductor layer SL that covers the lower insulating layer LIL may be formed, portions of the semiconductor layer SL may be etched, and insulating patterns IP that fill the etched portions of the semiconductor layer SL may be formed.

Subsequently, a preliminary stacked body pSTK including interlayer insulating layers IL and sacrificial layers SF that are alternately stacked may be formed. The interlayer insulating layers IL and the sacrificial layers SF may be stacked on top of each other in the Z direction. The interlayer insulating layers IL may be formed of an insulating material. For example, the interlayer insulating layers IL may be formed of an oxide layer (e.g., a silicon oxide layer). The sacrificial layers SF may be formed of a material that can be selectively removed in a subsequent process. The sacrificial layers SF may be formed of a material having an etch selectivity different from that of the interlayer insulating layers IL. For example, the sacrificial layers SF may be nitride layers.

Referring to FIG. 6C, openings passing through the preliminary stacked body pSTK may be formed. Portions of respective openings may be formed in the chip area CHA, and other portions of the openings may be formed in the guard area GDA. For example, each of the openings formed in the chip area CHA and the guard area GDA may have a circular or elliptical cross-sectional shape in the X-Y plane. In an example, among the openings, openings formed in the chip area CHA may have a circular or elliptical shape, and openings formed in the guard area GDA may have a slit shape.

Next, the cell plugs CPL and dummy cell plugs DCPL that fill the openings may be formed. Each of the cell plugs CPL may include a memory layer ML, a channel layer CH, and a core pillar CO. Each of the dummy cell plugs DCPL may include a dummy memory layer DML, a dummy channel layer DCH, and a dummy core pillar DCO. The dummy memory layer DML may contain the same material as the memory layer ML. The dummy channel layer DCH may contain the same material as the channel layer CH. The dummy core pillar DCO may contain the same material as the core pillar CO.

Referring to FIG. 6D, a step structure may be formed by etching a portion of the preliminary stacked body pSTK. The lengths of respective sacrificial layers SF in the X direction may be formed to be different from each other. For example, the step structure may be formed by sequentially etching the sacrificial layers SF to different lengths.

Further, the dummy cell plugs DCPL may be removed. Vertical structures VS may be formed in spaces from which the dummy cell plugs DCPL were removed. For example, as the dummy cell plugs DCPL are removed, some of the openings described in FIG. 6C may be reopened. Through the reopened openings, the side surface of the preliminary stacked body pSTK may be exposed. An insulating spacer may be formed along the exposed side surface of the preliminary stacked body pSTK. Also, a conductive pillar enclosed by the insulating spacer may be formed. The vertical structures VS may be formed to be coupled to the fourth lower plugs LP4. For example, the conductive pillar may contact the fourth lower plugs LP4.

Referring to FIG. 6E, the sacrificial layers SF may be replaced with conductive layers CD, whereby a stacked body STK may be formed. For example, the sacrificial layers SF may be selectively removed, and spaces from which the sacrificial layers SF were removed may be filled with a conductive material to form the conductive layers CD.

Then, first upper plugs UP1, first upper lines UL1, second upper plugs UP2, second upper lines UL2, and the third upper plugs UP3 may be formed on the stacked body STK. The first upper plugs UP1, the first upper lines UL1, the second upper plugs UP2, and the second upper lines UL2 may be formed in the guard area GDA. The first upper plugs UP1, the first upper lines UL1, the second upper plugs UP2, the second upper lines UL2, and the third upper plugs UP3 may be enclosed by an upper insulating layer UIL. Further, upper lines and upper plugs that are coupled to the contacts CT may also be formed in the chip area CHA. Although not illustrated in the drawings, upper lines and upper plugs that are coupled to the cell plugs CPL may additionally be formed.

For example, after a first insulating layer having a thickness is formed, a partial region of the first insulating layer may be etched, and the first upper plugs UP1 may be formed in the etched region. After a second insulating layer that covers the first upper plugs UP1 is formed, a partial region of the second insulating layer may be etched, and the first upper lines UL1 may be formed in the etched region. In this way, the upper lines and the upper plugs may be sequentially formed in the Z direction.

Subsequently, test electrodes TE coupled to the chip guard GD may be formed. The test electrodes TE may be electrically connected to the vertical structures VS through the upper lines (e.g., UL1 and UL2) and the upper plugs (e.g., UP1, UP2, and UP3). The test electrodes TE may be formed to be spaced apart from each other, wherein the cell plugs CPL are disposed between the test electrodes TE. For example, the test electrodes TE may be arranged to either side of the cell plugs CPL and the contacts CT.

Thereafter, whether defects have occurred at a level corresponding to the stacked body STK may be detected through the test electrodes TE. For example, a test circuit or a separate test device may measure the resistance of the chip guard GD through the test electrodes TE. The test circuit or the test device may monitor, using the test electrodes TE, whether defects related to the chip guard GD have occurred at a level corresponding to the stacked body STK.

The manufacturing method described above with reference to FIGS. 6A to 6E serves only an example and does not limit the scope of the present disclosure. For example, the order between some processes may vary, or some processes may be skipped, or some processes may be replaced with similar processes.

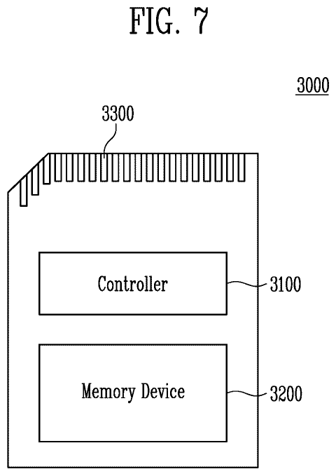

FIG. 7 is a diagram illustrating a memory card system to which a memory device according to the present disclosure is applied.

Referring to FIG. 7, a memory card system 3000 includes a controller 3100, a memory device 3200, and a connector 3300.

The controller 3100 may be connected to the memory device 3200. The controller 3100 may access the memory device 3200. For example, the controller 3100 may control a program operation, a read operation, or an erase operation of the memory device 3200 or control background operations of the memory device 3200. The controller 3100 may provide an interface between the memory device 3200 and a host. The controller 3100 may run firmware for controlling the memory device 3200. In an embodiment, the controller 3100 may include components, such as random-access memory (RAM), a processing unit, a host interface, a memory interface, and an error correction circuit.

The controller 3100 may communicate with an external device through the connector 3300. The controller 3100 may communicate with an external device (e.g., a host) based on a specific communication standard. For example, the controller 3100 may communicate with the external device through at least one of various communication standards, such as universal serial bus (USB), multimedia card (MMC), embedded MMC (eMMC), peripheral component interconnection (PCI), PCI-express (PCI-E), an advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). For example, the connector 3300 may be defined by at least one of the above-described various communication standards.

The memory device 3200 may include a plurality of memory cells. The controller 3100 and the memory device 3200 may be integrated into a single semiconductor device to form a memory card. For example, the controller 3100 and the memory device 3200 may be integrated into a single semiconductor device and may then form a memory card, such as a PC card (personal computer memory card international association: PCMCIA), a compact flash card (CF), a smart media card (SM or SMC), a memory stick, a multimedia card (MMC, RS-MMC, MMCmicro or eMMC), a SD card (SD, miniSD, microSD, or SDHC), or universal flash storage (UFS).

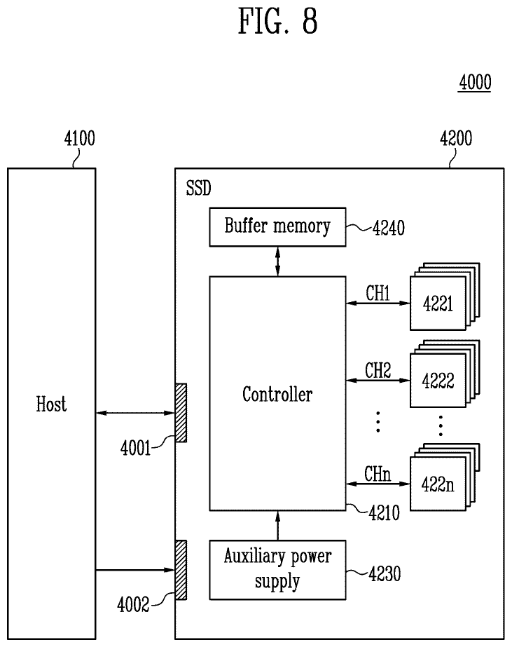

FIG. 8 is a diagram illustrating a solid-state drive (SSD) system to which a memory device according to the present disclosure is applied.

Referring to FIG. 8, an SSD system 4000 may include a host 4100 and an SSD 4200. The SSD 4200 may exchange signals with the host 4100 through a signal connector 4001 and may receive power through a power connector 4002. The SSD 4200 may include a controller 4210, a plurality of memory devices 4221 to 422n, an auxiliary power supply 4230, and buffer memory 4240.

The controller 4210 may control the plurality of memory devices 4221 to 422n in response to signals received from the host 4100. For example, the signals may indicate signals based on the interfaces of the host 4100 and the SSD 4200. For example, the signals may be signals defined by at least one interface, such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n may include a plurality of memory cells which store data. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied with a supply voltage from the host 4100, and it may be charged. The auxiliary power supply 4230 may provide the supply voltage of the SSD 4200 when the supply of power from the host 4100 is absent or outside of a voltage tolerance. For example, the auxiliary power supply 4230 may be located inside the SSD 4200 or located outside the SSD 4200. For example, the auxiliary power supply 4230 may be located on a main board, and it may also provide auxiliary power to the SSD 4200.

The buffer memory 4240 may function as buffer memory for the SSD 4200. For example, the buffer memory 4240 may store data received from the host 4100 or data received from the plurality of memory devices 4221 to 422n, or it may store metadata (e.g., mapping tables) of the memory devices 4221 to 422n. The buffer memory 4240 may include volatile memory, such as DRAM, SDRAM, DDR SDRAM, and LPDDR SDRAM, or nonvolatile memory, such as FRAM, ReRAM, STT-MRAM, and PRAM.

Some embodiments of the present disclosure may improve the quality of a memory device by enhancing the ability to identify defects occurring in an area outside a chip area.

What is claimed is:

1. A memory device, comprising:
a stacked body in which conductive layers and interlayer insulating layers are alternately stacked in a stacking direction;
a chip guard enclosing a chip area of the stacked body, the chip guard penetrating through the stacked body in the stacking direction; and
test electrodes electrically coupled to the chip guard,
wherein the test electrodes are spaced apart from each other, and at least a portion of the chip area is disposed between the test electrodes.

2. The memory device according to claim 1, wherein the chip guard comprises:
a vertical structure penetrating through the stacked body;
at least one upper line and at least one upper plug which are located over the stacked body; and
at least one lower line and at least one lower plug which are located under the stacked body.

3. The memory device according to claim 2, wherein at least one of the test electrodes is coupled to the at least one upper line.

4. The memory device according to claim 2, wherein the vertical structure comprises:
a plurality of pillar structures extending in the stacking direction and arranged along a first direction crossing the stacking direction.

5. The memory device according to claim 2, wherein the vertical structure comprises a plate extending along a first direction crossing the stacking direction.

6. The memory device according to claim 1, wherein the test electrodes are arranged symmetrically with respect to the center of the chip area enclosed by the chip guard.

7. The memory device according to claim 1, wherein:
a first test electrode of the test electrodes is coupled to the chip guard, and
a second test electrode of the test electrodes is coupled to the chip guard across the chip area from the first test electrode.

8. The memory device according to claim 1, wherein the test electrodes extend from the chip guard into the chip area.

9. The memory device according to claim 1, further comprising:
a test circuit connected to the test electrodes,
wherein the test circuit is configured to determine, using an electrical signal input to the chip guard, whether a defect has occurred in the stacked body.

10. The memory device according to claim 9, wherein the test circuit is configured to determine whether a defect has occurred in the stacked body using resistance gradient information obtained through the test electrodes.

11. The memory device according to claim 1, further comprising:
a detection circuit disposed between the chip area and the chip guard.

12. The memory device according to claim 11, wherein the detection circuit comprises:
at least one upper detection line and at least one upper detection plug which are located over the stacked body; and
at least one lower detection line and at least one lower detection plug which are located under the stacked body.

13. The memory device according to claim 11, wherein the detection circuit does not penetrate the stacked body.

14. The memory device according to claim 1, further comprising:
cell plugs penetrating through the stacked body in the chip area; and
contacts respectively coupled to the conductive layers in the chip area.

15. The memory device according to claim 14, further comprising:
a semiconductor layer below the stacked body, wherein the cell plugs contact the semiconductor layer.

16. A method of manufacturing a memory device, the method comprising:
forming a stacked body in which sacrificial layers and interlayer insulating layers are alternately stacked;
forming first and second sets of openings passing through the stacked body;
forming cell plugs filling the first set of the openings;
forming a vertical structure filling the second set of the openings;
replacing the sacrificial layers with conductive layers;
forming a chip guard, wherein the chip guard includes the vertical structure;
forming test electrodes that are electrically connected to the chip guard and to a test circuit,
wherein the test circuit is configured to determine, using an electrical signal input to the chip guard through the test electrodes, whether a defect has occurred in the stacked body.

17. The method according to claim 16, further comprising, before the stacked body is formed,
forming a lower insulating layer; and
forming at least one lower line and at least one lower plug that are enclosed by the lower insulating layer.

18. The method according to claim 17, wherein forming the vertical structure comprises:
forming the vertical structure to be coupled to the at least one lower line and the at least one lower plug.

19. The method according to claim 16, further comprising, before the test electrodes are formed,
forming an upper insulating layer on the stacked body; and
forming at least one upper line and at least one upper plug that are enclosed by the upper insulating layer.

20. The method according to claim 16, wherein forming the test electrodes comprises:
forming the test electrodes to be spaced apart from each other, wherein the cell plugs are disposed between the test electrodes.
